(19) United States
(12) Patent Application Publication
(10) Pub. No.: US 2026/0052868 A1
(43) Pub. Date: Feb. 19, 2026

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Du CHEN, Beijing (CN); Zhiwen CHU, Beijing (CN); Chang LUO, Beijing (CN); Jianmin SHE, Beijing (CN); Ping WEN, Beijing (CN); Hongwei MA, Beijing (CN); Yi ZHANG, Beijing (CN); Ke LIANG, Beijing (CN)

(21) Appl. No.: 19/475,319

(22) PCT Filed: Oct. 22, 2024
(86) PCT No.: PCT/CN2024/126257

§ 371 Date: Oct. 14, 2025

(30) Foreign Application Priority Data
Nov. 22, 2023 (CN) 202311570147.X

(51) Int. Cl. H10K 59/131

(52) U.S. Cl. CPC H10K 59/131

(57) ABSTRACT

A display substrate includes a signal transmission layer, at least two signal interconnection layers laminated one on another, and a first signal end. The signal interconnection layers include a first signal interconnection layer coupled to the signal transmission layer and a second signal interconnection layer coupled to the first signal end; a first contact region is provided between the signal transmission layer and the first signal interconnection layer; the first signal interconnection layer includes a first portion, the second signal interconnection layer includes a second portion, an interconnection region is formed between the second portion and the first portion, and the first portion is coupled to the second portion at the interconnection region; and an orthographic projection of the interconnection region onto the base substrate at least partially overlaps with an orthographic projection of the first contact region onto the base substrate.

### CROSS-REFERENCE TO RELATED APPLICATION

This application is the U.S. national phase of PCT Application No. PCT/CN2024/126257 filed on Oct. 22, 2024, which claims a priority of the Chinese patent application No. 202311570147.X filed in China on Nov. 22, 2023, which are incorporated herein by reference in their entireties.

### TECHNICAL FIELD

The present disclosure relates to the field of display technology, in particular to a display substrate and a display device.

### BACKGROUND

Along with the continuous development of the display technology, more and more types of display products occur, and an application field thereof become wider and wider. In order to meet the requirements in different application scenarios, sizes of the display products also become more and more diversified. A large-size display product is more sensitive to uniformity of a signal transmitted by a large-area signal transmission layer in the display product, so there is an urgent need to improve the uniformity of the signal transmitted by the signal transmission layer in the display product.

### SUMMARY

An object of the present disclosure is to provide a display substrate and a display device.

In order to achieve the above-mentioned object, the present disclosure provides the following technical solutions.

In a first aspect, the present disclosure provides in some embodiments a display substrate, including a display region and a peripheral region located around the display region. The display substrate further includes: a signal transmission layer, the signal transmission layer extending from the display region to the peripheral region; and at least two signal interconnection layers laminated one on another, and a first signal end, the at least two signal interconnection layers and the first signal end being arranged at the peripheral region, adjacent signal interconnection layers in the at least two signal interconnection layers being coupled to each other; the at least two signal interconnection layers include a first signal interconnection layer and a second signal interconnection layer, at least a portion of the second signal interconnection layer is arranged between the first signal interconnection layer and a base substrate of the display substrate, the second signal interconnection layer is coupled to the first signal end, and the first signal interconnection layer is coupled to the signal transmission layer; a first contact region is provided between the signal transmission layer and the first signal interconnection layer; the first signal interconnection layer includes a first portion, the second signal interconnection layer includes a second portion, an interconnection region is formed between the second portion and the first portion, and the first portion is coupled to the second portion at the interconnection region; and an orthographic projection of the interconnection region onto the base substrate at least partially overlaps with an orthographic projection of the first contact region onto the base substrate.

Optionally, the first portion is arranged at a surface of the second portion distal to the base substrate; or the first portion is coupled in parallel with the second portion.

Optionally, the first portion is directly lapped onto the second portion.

Optionally, the display substrate further includes an insulation layer, and the insulation layer is arranged between the first signal interconnection layer and the second signal interconnection layer; and the insulation layer is provided with a first via-hole, the first portion is located in the first via-hole, and the first portion is in contact with the surface of the second portion distal to the base substrate; or the insulation layer is provided with at least two second via-holes, and the first portion is coupled in parallel with the second portion through the at least two second via-holes.

Optionally, the signal transmission layer includes a cathode layer; and the display substrate further includes an anode layer, and the first signal interconnection layer is arranged at a same layer, and made of a same material, as the anode layer.

Optionally, the peripheral region includes a lower frame region; the display substrate further includes: a power source connection line and at least two power source signal input ends, the at least two power source signal input ends and the power source connection line being arranged at the lower frame region; and a plurality of power source lines, the plurality of power source lines being arranged at the display region; the power source connection line is coupled to the plurality of power source lines, and at least a portion of an orthographic projection of the power source connection line onto the base substrate is arranged between an orthographic projection of the first signal interconnection layer onto the base substrate and the display region; and the power source connection line is further coupled to the at least two power source signal input ends, and the at least two power source signal input ends are arranged at a side of the power source connection line distal to the display region.

Optionally, the first signal interconnection layer surrounds the display region.

Optionally, the at least two signal interconnection layers further include a third signal interconnection layer, at least a portion of the third signal interconnection layer is arranged between the second signal interconnection layer and the base substrate, and the second signal interconnection layer is coupled to the first signal end through the third signal interconnection layer.

Optionally, the display substrate further includes a first metal layer and a second metal layer arranged sequentially in that order in a direction away from the base substrate, the second signal interconnection layer is arranged at the second metal layer, and the third signal interconnection layer is arranged at the first metal layer.

Optionally, the at least two signal interconnection layers further include a third signal interconnection layer and a fourth signal interconnection layer, and in a direction away from the base substrate, the fourth signal interconnection layer, the third signal interconnection layer and the second signal interconnection layer are arranged sequentially; and the second signal interconnection layer is coupled to the first signal end through the third signal interconnection layer and the fourth signal interconnection layer.

Optionally, the display substrate further includes a first metal layer, a second metal layer and a third metal layer arranged sequentially in that order in the direction away from the base substrate; and the second signal interconnection layer is arranged at the third metal layer, the third signal interconnection layer is arranged at the second metal layer, and the fourth signal interconnection layer is arranged at the first metal layer.

Optionally, the second signal interconnection layer surrounds the display region.

Optionally, the power source connection line includes a connection body and a connection protrusion coupled to each other, the connection body is arranged between the connection protrusion and the display region, the connection body is coupled to the plurality of power source lines, and the connection protrusion is coupled to the power source signal input end; and at least a portion of an orthographic projection of the connection body onto the base substrate is arranged between the orthographic projection of the first signal interconnection layer onto the base substrate and the display region; an orthographic projection of the connection protrusion onto the base substrate at least partially overlaps with the orthographic projection of the first signal interconnection layer onto the base substrate; and/or the orthographic projection of the connection protrusion onto the base substrate at least partially overlaps with an orthographic projection of the second signal interconnection layer onto the base substrate.

Optionally, the display substrate further includes a first metal layer, and the second signal interconnection layer is arranged at the first metal layer.

Optionally, the power source connection line includes a connection body and a connection protrusion coupled to each other, the connection body is arranged between the connection protrusion and the display region, the connection body is coupled to the plurality of power source lines, and the connection protrusion is coupled to the power source signal input end; and at least a portion of an orthographic projection of the connection body onto the base substrate is arranged between the orthographic projection of the first signal interconnection layer onto the base substrate and the display region; an orthographic projection of the connection protrusion onto the base substrate does not overlap with the orthographic projection of the first signal interconnection layer onto the base substrate; and/or the orthographic projection of the connection protrusion onto the base substrate does not overlap with an orthographic projection of the second signal interconnection layer onto the base substrate; and the power source connection line is arranged at a same layer, and made of a same material, as the second signal interconnection layer.

Optionally, the first signal interconnection layer surrounds the display region, at least one first aperture region is formed at the lower frame region, and the connection protrusion is arranged at a corresponding first aperture region; and/or the second signal interconnection layer surrounds the display region, at least one second aperture region is formed at the lower frame region, and the connection protrusion is arranged at a corresponding second aperture region.

Optionally, the display substrate includes at least two power source signal input ends and at least two first signal ends; the at least two power source signal input ends include at least one power source terminal group, and a power source terminal group in the at least one power source terminal group includes two power source signal input ends of the at least two power source signal input ends arranged in a first direction; the at least two first signal ends include at least one first terminal group, and a first terminal group in the at least one first terminal group includes two first signal ends of the at least two first signal ends arranged in the first direction; and an orthographic projection of the power source terminal group onto the base substrate is arranged between orthographic projections of the two first signal ends in a corresponding first terminal group onto the base substrate.

Optionally, the power source connection line includes a connection body and at least one connection protrusion, the connection body is coupled to the at least one connection protrusion, the connection body is arranged between the at least one connection protrusion and the display region, the connection body is coupled to the plurality of power source lines, the at least one connection protrusion corresponds to the at least one power source terminal group respectively, and the connection protrusion is coupled to the power source signal input ends in a corresponding power source terminal group.

Optionally, the peripheral region includes a first binding region and a second binding region; the first binding region is arranged between the second binding region and the display region; the display substrate further includes a flexible circuit board and at least one driving chip, the at least one driving chip is bound to the first binding region, and the flexible circuit board is bound to the second binding region; the flexible circuit board is coupled to the power source signal input ends and the first signal ends; and the power source signal input ends and the first signal ends are arranged between the second binding region and the display region, and an orthographic projection of the first binding region onto the base substrate is arranged between orthographic projections of the two power source signal input ends in a corresponding power source terminal group onto the base substrate.

In a second aspect, the present disclosure provides in some embodiments a display substrate, including a display region and a peripheral region located around the display region. The display substrate further includes: a signal transmission layer, wherein the signal transmission layer extends from the display region to the peripheral region; and at least two signal interconnection layers laminated one on another, and a first signal end, wherein the at least two signal interconnection layers and the first signal end are arranged at the peripheral region, wherein adjacent signal interconnection layers in the at least two signal interconnection layers are coupled to each other; the at least two signal interconnection layers include a first signal interconnection layer and a second signal interconnection layer, at least a portion of the second signal interconnection layer is arranged between the first signal interconnection layer and a base substrate of the display substrate, the second signal interconnection layer is coupled to the first signal end, and the first signal interconnection layer is coupled to the signal transmission layer; a first interconnection region is provided between the signal transmission layer and the first signal interconnection layer, the first interconnection region includes a plurality of sub-regions arranged sequentially in a direction from the display region to the peripheral region, and the signal transmission layer is coupled to the first signal interconnection layer at the plurality of sub-regions; the first signal interconnection layer includes a first portion, the second signal interconnection layer includes a second portion, a second interconnection region is formed between the second portion and the first portion, and the first portion is coupled to the second portion at the second interconnection region; an orthographic projection of a sub-region in the plurality of sub-regions proximate to the display region onto the base substrate at least partially overlaps with an orthographic projection of the first contact region onto the base substrate; and an orthographic projection of a sub-region in the plurality of sub-regions distal to the display region onto the base substrate at least partially overlaps with the orthographic projection of the first contact region onto the base substrate.

In a third aspect, the present disclosure provides in some embodiments a display device including the above-mentioned display substrate.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. In these drawings,

FIG. 1 is a schematic view showing an overall structure of a signal transmission layer and a signal interconnection layer in a display substrate according to an embodiment of the present disclosure;

FIG. 2 is a schematic view showing the layout of a lower frame region of the display substrate according to an embodiment of the present disclosure;

FIG. 3 is a schematic view showing the layout of the lower frame region in FIG. 2 after a cathode layer and structures in a display region are removed;

FIG. 4 is a schematic view showing the layout of the lower frame region in FIG. 3 after a first signal interconnection layer and a second signal interconnection layer are removed;

FIG. 5 is a sectional view of the lower frame region in FIG. 2 along line C1C2;

FIG. 6 is a schematic view showing a connection relationship among signal interconnection layers according to an embodiment of the present disclosure;

FIG. 7 is a schematic view showing a connection relationship among the signal interconnection layers according to an embodiment of the present disclosure;

FIG. 8 is a schematic view showing the layout of the lower frame region of the display substrate according to an embodiment of the present disclosure;

FIG. 9 is a schematic view showing the layout of the lower frame region in FIG. 8 after the cathode layer and the structures in the display region are removed;

FIG. 10 is a schematic view showing the layout of the lower frame region in FIG. 9 after the first signal interconnection layer and the second signal interconnection layer are removed;

FIG. 11 is a sectional view of the lower frame region in FIG. 8 along line D1D2;

FIG. 12 is a schematic view showing a connection relationship among the signal interconnection layers according to an embodiment of the present disclosure;

FIG. 13 is a schematic view showing a connection relationship among the signal interconnection layers according to an embodiment of the present disclosure;

FIG. 14 is a schematic view showing the layout of the lower frame region of the display substrate according to an embodiment of the present disclosure;

FIG. 15 is a schematic view showing the layout of the lower frame region in FIG. 14 after the cathode layer and the structures in the display region are removed;

FIG. 16 is a schematic view showing the layout of the lower frame region in FIG. 14 after the first signal interconnection layer and the second signal interconnection layer are removed;

FIG. 17 is a sectional view of the lower frame region in FIG. 14 along line E1E2;

FIG. 18 is a schematic view showing a connection relationship among the signal interconnection layers according to an embodiment of the present disclosure;

FIG. 19 is a schematic view showing a connection relationship among the signal interconnection layers according to an embodiment of the present disclosure;

FIG. 20 is a sectional view of the display substrate according to an embodiment of the present disclosure;

FIG. 21 is another sectional view of the display substrate according to an embodiment of the present disclosure; and

FIG. 22 is a sectional view of the lower frame region in FIG. 2 along line F1F2.

### DETAILED DESCRIPTION

In order to further describe a display substrate and a display device provided in the embodiments of the present disclosure, the following description will be given in conjunction with the drawings.

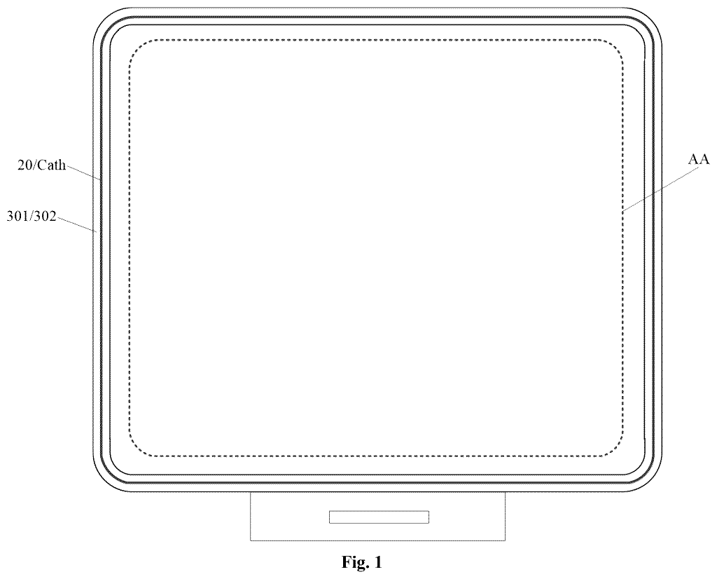

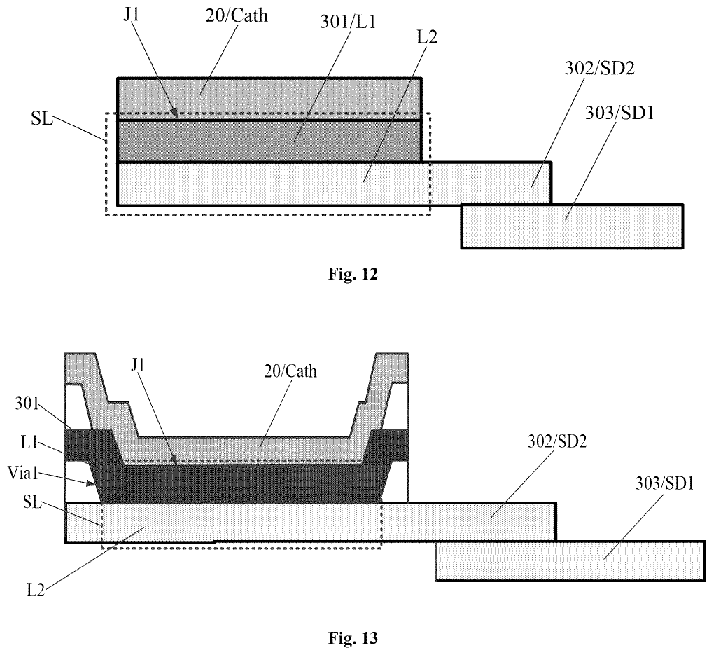

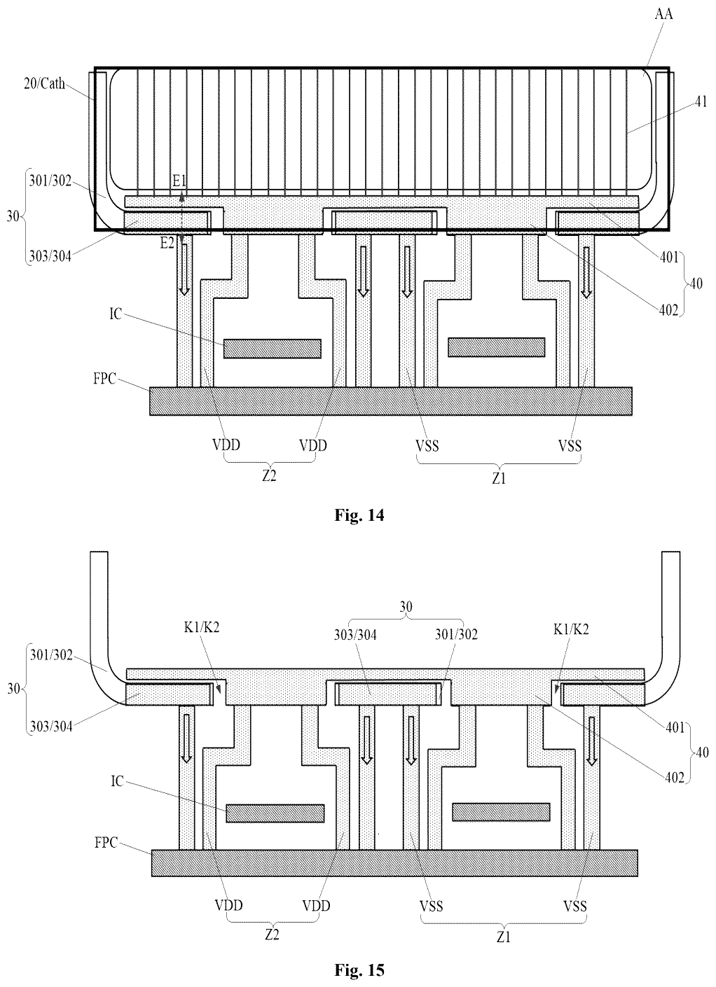

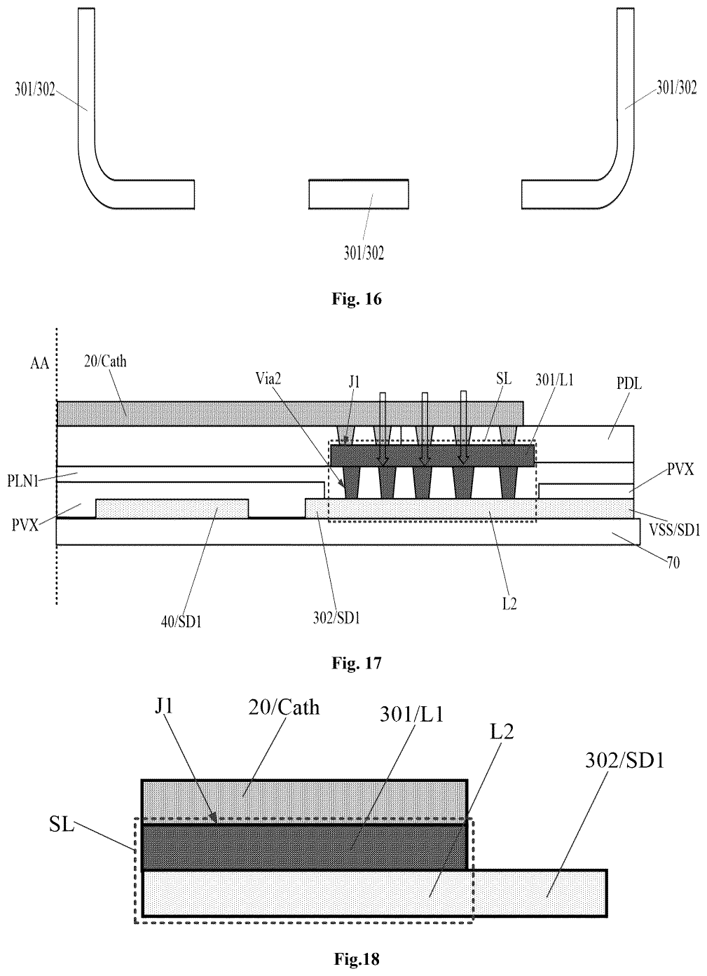

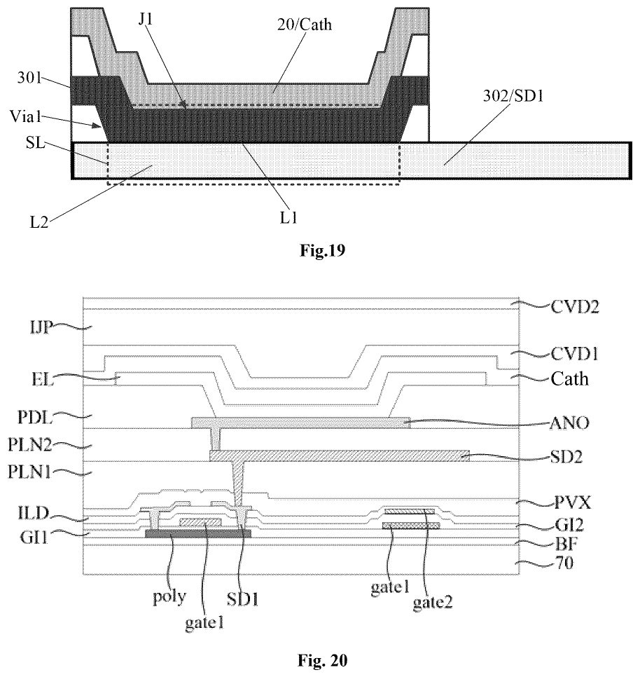

As shown in FIGS. 1, 2, 5-8, 11-14, and 11-19, the present disclosure provides in some embodiments a display substrate, which includes a display region AA and a peripheral region located around the display region AA. The display substrate further includes: a signal transmission layer 20, at least two signal interconnection layers 30 laminated one on another, and a first signal end VSS. The signal transmission layer 20 extends from the display region AA to the peripheral region, and the signal interconnection layers and the first signal end VSS are all arranged at the peripheral region.

Adjacent signal interconnection layers 30 in the at least two signal interconnection layers 30 are coupled to each other; the at least two signal interconnection layers 30 include a first signal interconnection layer 301 and a second signal interconnection layer 302, at least a portion of the second signal interconnection layer 302 is arranged between the first signal interconnection layer 301 and a base substrate 70 of the display substrate, the first signal interconnection layer 301 is coupled to the signal transmission layer 20, and the second signal interconnection layer 302 is coupled to the first signal end VSS.

A first contact region J1 is provided between the signal transmission layer 20 and the first signal interconnection layer 301; the first signal interconnection layer 301 includes a first portion L1, the second signal interconnection layer 302 includes a second portion L2, an interconnection region SL is formed between the second portion L2 and the first portion L1, and the first portion LI is coupled to the second portion L2 at the interconnection region SL; and an orthographic projection of the interconnection region SL onto the base substrate at least partially overlaps with an orthographic projection of the first contact region J1 onto the base substrate.

Illustratively, the display substrate includes the display region AA and the peripheral region. The peripheral region surrounds the display region AA. For example, the display region AA includes a rectangular display region AA, and the peripheral region includes an upper frame region, a lower frame region, a left frame region and a right frame region. A driving chip IC of the display substrate is arranged at the lower frame region.

Illustratively, the display substrate includes a plurality of subpixels, the plurality of subpixels is arranged at the display region AA, and a plurality of subpixel driving circuits of the plurality of subpixels is arranged in an array form. The plurality of subpixel driving circuits includes a plurality of rows of subpixel driving circuits and a plurality of columns of subpixel driving circuits. The plurality of rows of subpixel driving circuits is arranged in a second direction, and each row of subpixel driving circuits includes a plurality of subpixel driving circuits arranged in a first direction. The plurality of columns of subpixel driving circuits is arranged in the first direction, and each column of subpixel driving circuits includes a plurality of subpixel driving circuits arranged in the second direction. For example, the first direction intersects the second direction. For example, the first direction includes a transverse direction, and the second direction includes a vertical direction.

For example, the subpixel includes a subpixel driving circuit and a light-emitting element. The subpixel driving circuit is coupled to an anode of the light-emitting element, and configured to provide a driving signal to the light-emitting element, so as to drive the light-emitting element to emit light. The light-emitting element includes the anode and a light-emitting functional layer, and the anode is arranged between the light-emitting functional layer and the base substrate. The display substrate further includes a cathode layer, the cathode layer is arranged at a side of the light-emitting functional layer away from the base substrate, the cathode layer is formed as an entire-layer structure covering the entire display region AA, and the light-emitting functional layer emits light under the effect of an electric field formed by the anode and the cathode layer, so as to achieve a light-emitting function of the subpixel.

Illustratively, the display substrate further includes the signal transmission layer 20, and the signal transmission layer 20 has a larger area. For example, the signal transmission layer 20 extends from an upper edge of the display region AA to a lower edge of the display region AA; and/or the signal transmission layer 20 extends a left edge of the display region AA to a right edge of the display region AA. The signal transmission layer 20 includes a long signal line or a transmission layer as an entire surface, but the present disclosure is not limited thereto.

Illustratively, the display substrate further includes at least two signal interconnection layers, and the signal interconnection layers are arranged at different layers, but the present disclosure is not limited thereto. The display substrate further includes at least one first signal end VSS, the first signal end VSS is configured to transmit a first signal, and the first signal is transmitted between the signal transmission layer 20 and the first signal end VSS through the signal interconnection layers.

Illustratively, the at least two signal interconnection layers include a first signal interconnection layer 301 and a second signal interconnection layer 302, the first signal interconnection layer 301 is directly or indirectly coupled to the signal transmission layer 20, and the second signal interconnection layer 302 is directly or indirectly coupled to the first signal end VSS.

Illustratively, the first contact region J1 is provided between the signal transmission layer 20 and the first signal interconnection layer 301, and the signal transmission layer 20 is electrically coupled to the first signal interconnection layer 301 at the first contact region J1.

Illustratively, the first signal interconnection layer 301 includes the first portion L1, the second signal interconnection layer 302 includes the second portion L2, and the first signal is transmitted through the first portion L1 and the second portion L2, but the present disclosure is not limited thereto. For example, the first portion L1 surrounds the display region AA or at least partially surrounds the display region AA; and the second portion L2 surrounds the display region AA or at least partially surrounds the display region AA, but the present disclosure is not limited thereto.

Illustratively, a second contact region is formed between the second signal interconnection layer 302 and a conductive film layer thereunder, and the first contact region J1 does not overlap with the second contact region. For example, the first contact region J1 is arranged between the display region and the second contact region.

Based on the above-mentioned specific structure of the display substrate, in the embodiments of the present disclosure, the display substrate includes the signal transmission layer 20, the at least two signal interconnection layers 30 laminated one on another, and the first signal end VSS. The at least two signal interconnection layers 30 include the first signal interconnection layer 301 and the second signal interconnection layer 302, the first signal interconnection layer 301 is coupled to the signal transmission layer 20, and the second signal interconnection layer 302 is coupled to the first signal end VSS. The first contact region J1 is arranged between the signal transmission layer 20 and the first signal interconnection layer 301. The first signal interconnection layer 301 includes the first portion L1, the second signal interconnection layer 302 includes the second portion L2, and the interconnection region SL is formed between the second portion L2 and the first portion L1. The orthographic projection of the interconnection region SL onto the base substrate at least partially overlaps with the orthographic projection of the first contact region J1 onto the base substrate.

In the display substrate provided in the embodiments of the present disclosure, the signal transmission layer 20 is electrically coupled to the first signal end VSS through the first signal interconnection layer 301 and the second signal interconnection layer 302 sequentially. In a case that a signal is transmitted between the signal transmission layer 20 and the first signal end VSS, the signal transmission is achieved through the second portion L2 and the first portion L1 simultaneously. The signal transmission layer 20 is coupled to the first signal interconnection layer 301, so that the first signal interconnection layer 301 is electrically coupled to the signal transmission layer 20 at a plurality of frame regions. In this way, the signal is transmitted between the signal transmission layer and the signal interconnection layer in various direction, so as to better improve the uniformity of the signal transmitted by the signal transmission layer 20 in a display product, thereby enhancing the stability of the display effect and the uniformity of the display quality of the display substrate.

In the display substrate provided in the embodiments of the present disclosure, the signal is transmitted to the signal transmission layer 20 simultaneously through the second portion L2 and the first portion L1, so the signal is transmitted through the first signal interconnection layer 301 simultaneously in a multi-layered manner. In this way, even in a case that the first signal interconnection layer 301 has a small thickness, it is able to prevent the loading of the first signal interconnection layer 301 from being too large, and ensure that the first signal interconnection layer 301 is not damaged by the current during the transmission of the signal, thereby ensuring a good production yield of the display substrate.

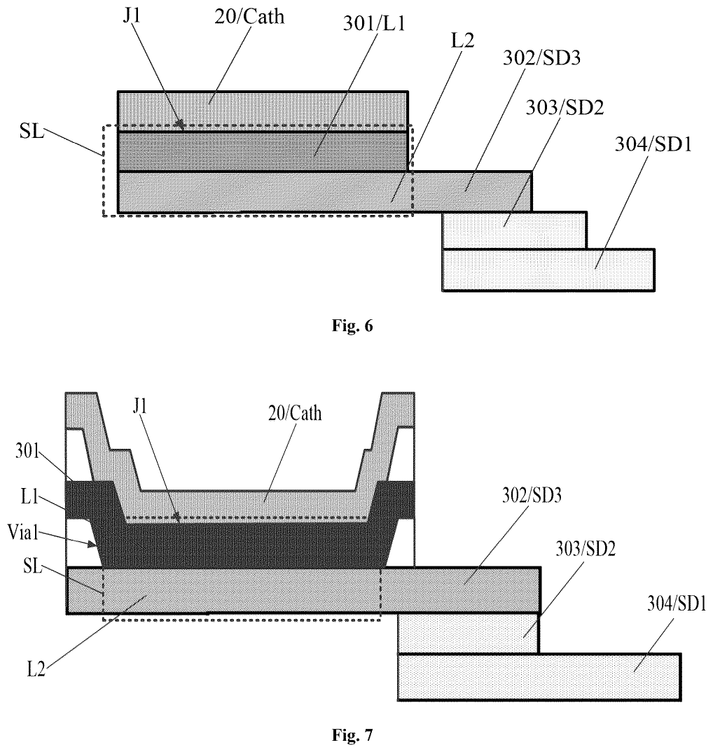

In some embodiments of the present disclosure, as shown in FIGS. 6-7, 12-13 and 18-19, the first portion L1 is arranged at a surface of the second portion L2 away from the base substrate; or as shown in FIGS. 5, 11 and 17, the first portion L1 is coupled in parallel with the second portion L2.

As shown in FIGS. 6, 12 and 18, for example, the first portion L1 is directly lapped onto the second portion L2. A region where the first portion L1 is lapped onto the second portion L2 surrounds the display region AA; or the region where the first portion LI is lapped onto the second portion L2 at least partially surrounds the display region AA.

As shown in FIGS. 7, 13 and 19, for example, the display substrate includes an insulation layer, and the insulation layer is arranged between the first signal interconnection layer 301 and the second signal interconnection layer 302. The insulation layer is provided with a first via-hole Vial, the first portion L1 is located in the first via-hole Vial, and the first portion L1 is in contact with the surface of the second portion L2 away from the base substrate. For example, the first via-hole Vial surrounds the display region AA; or the first via-hole Vial at least partially surrounds the display region AA.

As shown in FIGS. 5, 11 and 17, for example, for example, the display substrate includes an insulation layer, and the insulation layer is arranged between the first signal interconnection layer 301 and the second signal interconnection layer 302. The insulation layer is provided with at least two second via-holes Via2, and the first portion L1 is coupled in parallel with the second portion L2 through the at least two second via-holes Via2. For example, the second via-holes Via2 surround the display region AA; or the second via-holes Via2 at least partially surround the display region AA.

In the above-mentioned display substrate, the interconnection region SL is formed in various ways, so that the signal is transmitted simultaneously in a multi-layered manner through the first signal interconnection layer 301. In this way, even in a case that the first signal interconnection layer 301 has a small thickness, it is able to ensure that the first signal interconnection layer 301 is not damaged by the current during the transmission of the signal, thereby ensuring a good production yield of the display substrate in a better manner.

As shown in FIGS. 1, 2, 8 and 14, in some embodiments of the present disclosure, the signal transmission layer 20 includes a cathode layer Cath, the display substrate further includes an anode layer, and the first signal interconnection layer 301 is arranged at a same layer, and made of a same material, as the anode layer.

In a case that the first signal interconnection layer 301 is arranged at a same layer, and made of a same material, as the anode layer, the first signal interconnection layer 301 and the anode layer are formed simultaneously through a single patterning process, so it is unnecessary to provide an additional patterning process for forming the first signal interconnection layer 301, thereby to effectively simplify the manufacture of the display substrate, and reduce the manufacture cost of the display substrate.

Based on the above, the signal transmission layer 20 includes the cathode layer Cath, and a cathode current is transmitted from the cathode layer Cath to the first signal interconnection layer 301 in various directions, so as to improve the uniformity of the cathode current transmitted through the cathode layer Cath of the display product in a better manner. For example, the cathode current is transmitted from the cathode layer Cath to the first signal interconnection layer 301 at the upper frame region, the lower frame region, the left frame region and the right frame region, but the present disclosure is not limited thereto.

The anode layer has a small thickness, and the first signal interconnection layer 301 is arranged at a same layer, and made of a same material, as the anode layer so that the first signal interconnection layer 301 has a small thickness. In a case that the cathode current flows through the first signal interconnection layer 301, it is transmitted simultaneously through the first portion L1 and the second portion L2 at the interconnection region SL. Hence, the cathode current is transmitted simultaneously in a multi-layered manner in a case that it flows through the first signal interconnection layer 301. In this way, even in a case that the first signal interconnection layer 301 has a small thickness, it is able to prevent the first signal interconnection layer 301 from being damaged by the cathode current during the transmission of the cathode current, thereby ensuring a good production yield of the display substrate.

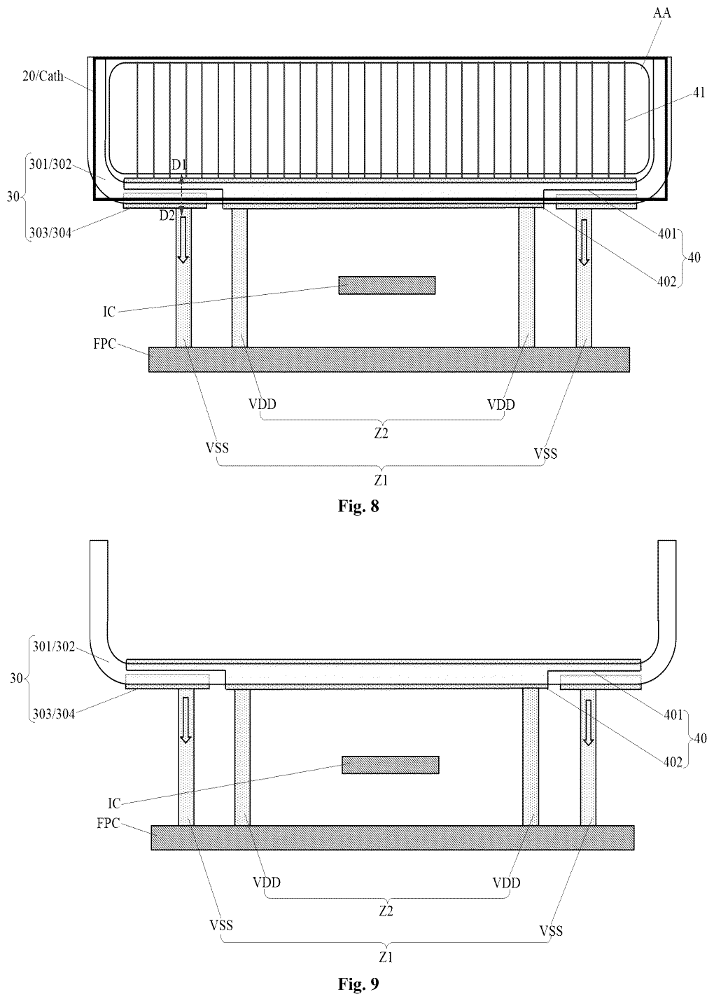

As shown in FIGS. 2 and 8, in some embodiments of the present disclosure, the peripheral region includes a lower frame region; the display substrate further includes a power source connection line 40, at least two power source signal input ends VDD, and a plurality of power source lines 41. The plurality of power source lines 41 extends from the display region AA to the lower frame region, and the at least two power source signal input ends VDD and the power source connection line 40 are arranged at the lower frame region. The power source connection line 40 is coupled to the plurality of power source lines 41, and at least a portion of an orthographic projection of the power source connection line 40 onto the base substrate is arranged between an orthographic projection of the first signal interconnection layer 301 onto the base substrate and the display region AA; and the power source connection line 40 is further coupled to the at least two power source signal input ends VDD, and the at least two power source signal input ends VDD are arranged at a side of the power source connection line 40 away from the display region AA.

Illustratively, the power source line 41 is arranged at the display region, but the present disclosure is not limited thereto.

Illustratively, at least a portion of the orthographic projection of the power source connection line 40 onto the base substrate and the orthographic projection of the first signal interconnection layer 301 onto the base substrate are arranged sequentially in that order in a direction away from the display region AA.

Illustratively, the plurality of power source lines 41 is arranged in the first direction, and each power source line 41 includes at least a portion extending in the second direction. The power source line 41 is respectively coupled to each of the subpixel driving circuits in a corresponding column. For example, the power source connection line 40 includes at least a portion extending in the first direction, and the power source connection line 40 is coupled to the plurality of power source lines 41.

Illustratively, the orthographic projection of the power source connection line 40 onto the base substrate at least partially overlaps with the orthographic projection of the first signal interconnection layer 301 onto the base substrate; and/or the orthographic projection of the power source connection line 40 onto the base substrate at least partially overlaps with the orthographic projection of the second signal interconnection layer 302 onto the base substrate; and/or the orthographic projection of the power source connection line 40 onto the base substrate at least partially overlaps with the orthographic projection of the signal transmission layer 20 onto the base substrate.

As shown in FIG. 1, in some embodiments of the present disclosure, the first signal interconnection layer 301 surrounds the display region AA.

In a case that the first signal interconnection layer 301 surrounds the display region AA, the first signal interconnection layer 301 is electrically coupled to the signal transmission layer 20 at a plurality of frame regions. In this way, the signal is transmitted between the signal transmission layer 20 and the signal interconnection layer 30 in various directions, so as to increase the quantity of transmission paths for the signal between the signal transmission layer 20 and the signal interconnection layer 30, thereby to improve the uniformity of the signal transmitted through the signal transmission layer 20 in the display product in a better manner.

As shown in FIG. 1, in some embodiments of the present disclosure, the second signal interconnection layer 302 surrounds the display region AA.

In a case that the second signal interconnection layer 302 surrounds the display region AA, the first signal interconnection layer 301 is electrically coupled to the second signal interconnection layer 302 at a plurality of frame regions. In this way, the signal is transmitted between the second signal interconnection layer 302 and the first signal interconnection layer 301 in various directions, and transmitted simultaneously through the first portion L1 and the second portion L2 in various directions, so as to balance the current density on the signal transmission layer 20 while ensuring the reliability, thereby to improve the uniformity of the signal transmitted through the signal transmission layer 20 in the display product.

In some embodiments of the present disclosure, the interconnection region SL surrounds the display region AA, and the signal is transmitted simultaneously through the first portion L1 and the second portion L2 in a case that the signal is transmitted between the second signal interconnection layer 302 and the signal transmission layer 20 in various directions, so as to ensure the normal use of the display substrate.

Illustratively, in a case that the display region AA includes a rectangular display region AA and the peripheral region includes an upper frame region, a lower frame region, a left frame region and a right frame region, the above-mentioned various directions include a transmission direction from the upper frame region to the display region AA, a transmission direction from the lower frame region to the display region AA, a transmission direction from the left frame region to the display region AA, and a transmission direction from the right frame region to the display region AA. However, the present disclosure is not limited thereto.

Illustratively, in a case that the display region AA includes a rectangular display region AA and the peripheral region includes an upper frame region, a lower frame region, a left frame region and a right frame region, the above-mentioned various directions include a transmission direction from the display region AA to the upper frame region, a transmission direction from the display region AA to the lower frame region, a transmission direction from the display region AA to the left frame region, and a transmission direction from the display region AA to the right frame region. However, the present disclosure is not limited thereto.

FIG. 22 shows a connection relationship among the signal transmission layer 20, the first signal interconnection layer 301 and the second signal interconnection layer 302. In FIGS. 22, 80 represents all film layers under the second signal interconnection layer 302.

As shown in FIGS. 8 to 13, in some embodiments of the present disclosure, the at least two signal interconnection layer further includes a third signal interconnection layer 303, at least a portion of the third signal interconnection layer 303 is arranged between the second signal interconnection layer 302 and the base substrate, and the second signal interconnection layer 302 is coupled to the first signal end VSS through the third signal interconnection layer 303.

Illustratively, the display substrate further includes a first metal layer and a second metal layer arranged sequentially in that order in a direction away from the base substrate, the second signal interconnection layer 302 is arranged at the second metal layer, and the third signal interconnection layer 303 is arranged at the first metal layer.

As shown in FIG. 20, for example, the display substrate includes a buffer layer BF, an active layer poly, a first gate insulation layer GI1, a first gate metal layer gate1, a second gate insulation layer GI2, a second gate metal layer gate2, an interlayer insulation layer ILD, a first source/drain metal layer SD1, a first planarization layer PLN1, a second source/drain metal layer SD2, a second planarization layer PLN2, an anode layer ANO, a pixel definition layer PDL, a light-emitting function layer EL, a cathode layer Cath, a first inorganic encapsulation layer CVD1, an organic encapsulation layer IJP, a second inorganic encapsulation layer CVD2, etc., which are arranged sequentially in that order in a direction away from the base substrate 70. The display substrate further includes, but not limited to, a passivation layer PVX.

Illustratively, the first metal layer includes the first source/drain metal layer SD1, and the second metal layer includes the second source/drain metal layer SD2, but the present disclosure is not limited thereto.

Illustratively, the first source/drain metal layer SD1 and/or the second source/drain metal layer SD2 include, but not limited to, a structure consisting of a titanium (Ti) layer, an aluminum (Al) layer and a Ti layer laminated one on another.

Illustratively, the first source/drain metal layer SD1 is used to form a source electrode and a drain electrode of a transistor in the display substrate. The first source/drain metal layer SD1 and/or the second source/drain metal layer SD2 are also used to form, but not limited to, a conductive connection member and a signal line.

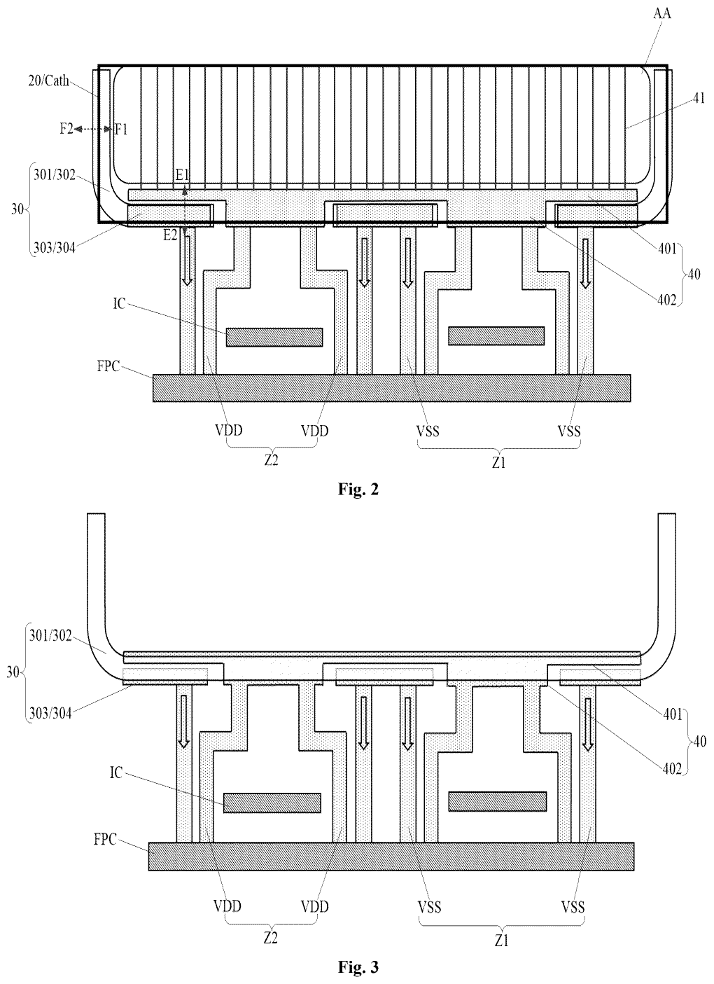

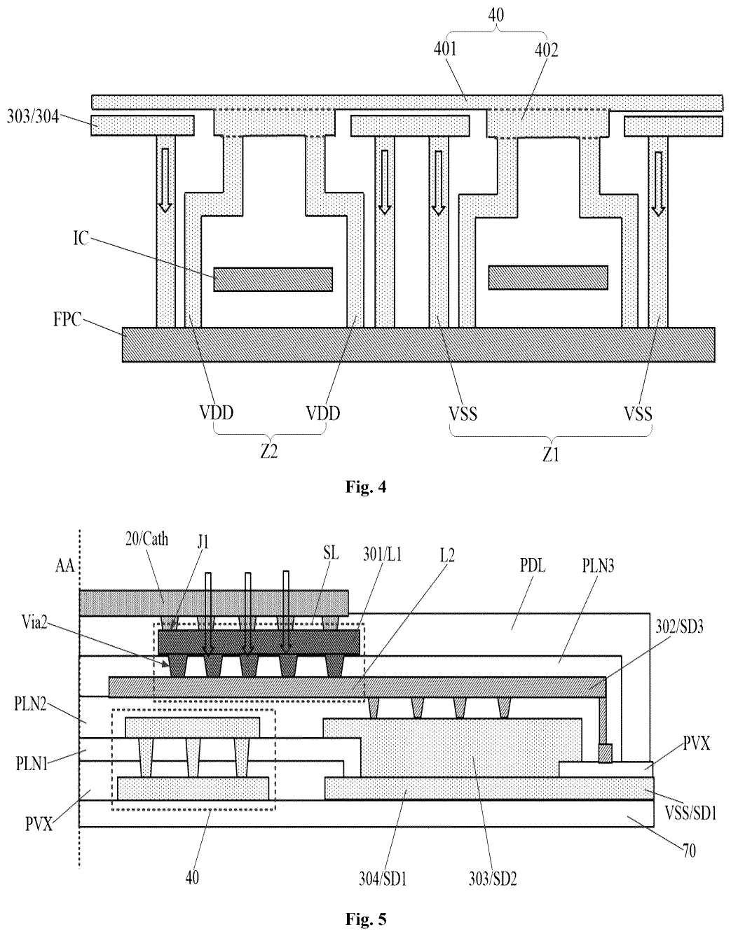

As shown in FIGS. 2 to 7, in some embodiments of the present disclosure, the at least two signal interconnection layers further include a third signal interconnection layer 303 and a fourth signal interconnection layer 304, and in a direction away from the base substrate, the fourth signal interconnection layer 304, the third signal interconnection layer 303 and the second signal interconnection layer 302 are arranged sequentially; and the second signal interconnection layer 302 is coupled to the first signal end VSS through the third signal interconnection layer 303 and the fourth signal interconnection layer 304.

Illustratively, the display substrate further includes a first metal layer, a second metal layer and a third metal layer arranged sequentially in that order in the direction away from the base substrate; and the second signal interconnection layer 302 is arranged at the third metal layer, the third signal interconnection layer 303 is arranged at the second metal layer, and the fourth signal interconnection layer 304 is arranged at the first metal layer.

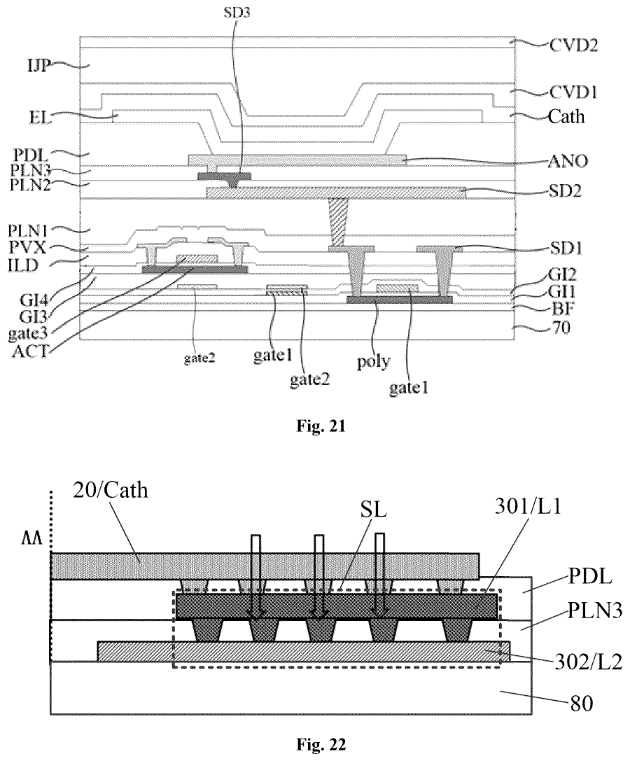

As shown in FIG. 21, for example, the display substrate includes a buffer layer BF, a first active layer poly, a first gate insulation layer GI1, a first gate metal layer gate1, a second gate insulation layer GI2, a second gate metal layer gate2, a third gate insulation layer GI3, a second active layer ACT, a fourth gate insulation layer GI4, a third gate metal layer gate3, an interlayer insulation layer ILD, a first source/drain metal layer SD1, a passivation layer PVX, a first planarization layer PLN1, a second source/drain metal layer SD2, a second planarization layer PLN2, a third source/drain metal layer SD3, a third planarization layer PLN3, an anode layer ANO, a pixel definition layer PDL, a light-emitting function layer EL, a cathode layer Cath, a first inorganic encapsulation layer CVD1, an organic encapsulation layer IJP, and a second inorganic encapsulation layer CVD2, which are arranged sequentially in that order in a direction away from the base substrate 70. The display substrate further includes a light-shielding layer arranged between the first active layer poly and the base substrate 70.

Illustratively, the first metal layer includes the first source/drain metal layer SD1, the second metal layer includes the second source/drain metal layer SD2, and the third metal layer includes the third source/drain metal layer SD3, but the present disclosure is not limited thereto.

Illustratively, the first source/drain metal layer SD1, the second source/drain metal layer SD2 and/or the third source/drain metal layer SD3 include, but not limited to, a structure consisting of a Ti layer, an Al layer and a Ti layer laminated one on another.

Illustratively, the first source/drain metal layer SD1 is used to form a source electrode and a drain electrode of a transistor in the display substrate. The first source/drain metal layer SD1, the second source/drain metal layer SD2 and the third source/drain metal layer SD3 are also used to form, but not limited to, a conductive connection member and a signal line.

As shown in FIGS. 2 and 8, in some embodiments of the present disclosure, the power source connection line 40 includes a connection body 401 and a connection protrusion 402 coupled to each other, the connection body 401 is arranged between the connection protrusion 402 and the display region AA, the connection body 401 is coupled to the plurality of power source lines 41, and the connection protrusion 402 is coupled to the power source signal input end VDD; and at least a portion of an orthographic projection of the connection body 401 onto the base substrate is arranged between the orthographic projection of the first signal interconnection layer 301 onto the base substrate and the display region AA; an orthographic projection of the connection protrusion 402 onto the base substrate at least partially overlaps with the orthographic projection of the first signal interconnection layer 301 onto the base substrate; and/or the orthographic projection of the connection protrusion 402 onto the base substrate at least partially overlaps with an orthographic projection of the second signal interconnection layer 302 onto the base substrate.

As shown in FIG. 5, for example, in a case that the display substrate includes the first source/drain metal layer SD1, the second source/drain metal layer SD2 and the third source/drain metal layer SD3, the power source connection line 40 includes a structure consisting of two layers laminated one on another, a first layer of the two layers is arranged at a same layer, and made of a same material, as the first source/drain metal layer SD1, and another layer of the two layers is arranged at a same layer, and made of a same material, as the second source/drain metal layer SD2.

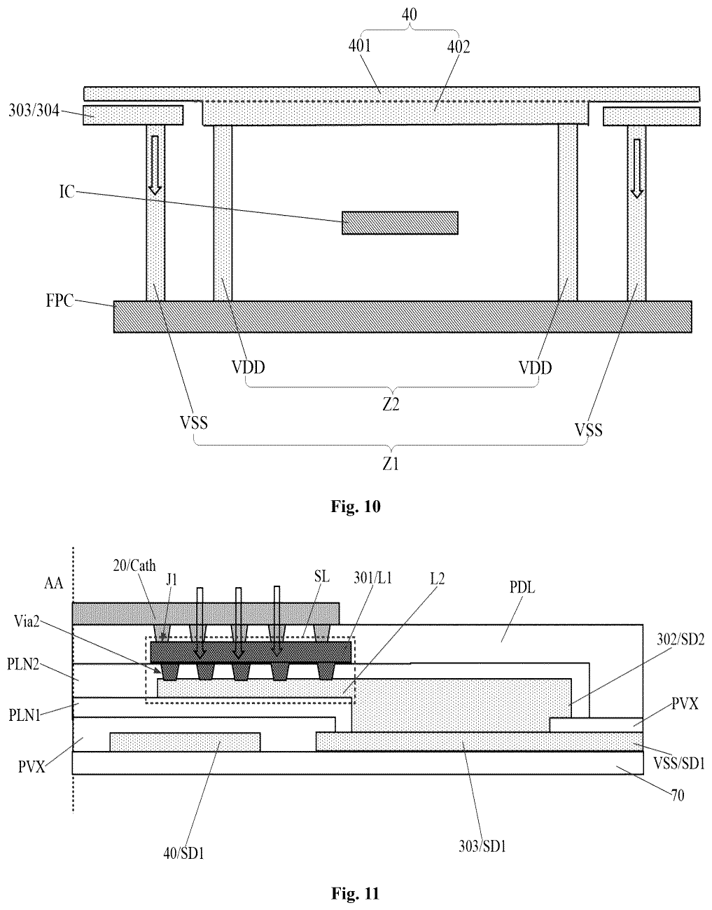

As shown in FIG. 11, for example, in a case that the display substrate includes the first source/drain metal layer SD1 and the second source/drain metal layer, the power source connection line 40 includes a single-layered structure, and the power source connection line 40 is arranged at a same layer, and made of a material, as the first source/drain metal layer SD1.

Illustratively, the orthographic projection of the connection body 401 onto the base substrate at least partially overlaps with the orthographic projection of the first signal interconnection layer 301 onto the base substrate; and/or the orthographic projection of the connection body 401 onto the base substrate at least partially overlaps with the orthographic projection of the second signal interconnection layer 302 onto the base substrate.

Based on the above, it is able to effectively reduce a layout space occupied by the power source connection line 40 and the signal interconnection layer at the lower frame region, ensure the insulation performance between the film layers for transmitting different signals, and ensure the reliability of the display substrate.

As shown in FIG. 17, in some embodiments of the present disclosure, the display substrate further includes a first metal layer, and the second signal interconnection layer 302 is arranged at the first metal layer.

Illustratively, the display substrate includes a buffer layer, an active layer, a first gate insulation layer, a first gate metal layer, a second gate insulation layer, a second gate metal layer, an interlayer insulation layer, a first source/drain metal layer, a first planarization layer, an anode layer, a pixel definition layer, a light-emitting function layer, a cathode layer, a first inorganic encapsulation layer, an organic encapsulation layer, a second inorganic encapsulation layer, etc., which are laminated one on another in a direction away from the base substrate. The display substrate further includes, but not limited to, a passivation layer.

As shown in FIGS. 14 to 17, in some embodiments of the present disclosure, the power source connection line 40 includes a connection body 401 and a connection protrusion 402 coupled to each other, the connection body 401 is arranged between the connection protrusion 402 and the display region AA, the connection body 401 is coupled to the plurality of power source lines 41, and the connection protrusion 402 is coupled to the power source signal input end VDD, and at least a portion of an orthographic projection of the connection body 401 onto the base substrate is arranged between the orthographic projection of the first signal interconnection layer 301 onto the base substrate and the display region AA; an orthographic projection of the connection protrusion 402 onto the base substrate does not overlap with the orthographic projection of the first signal interconnection layer 301 onto the base substrate; and/or the orthographic projection of the connection protrusion 402 onto the base substrate does not overlap with an orthographic projection of the second signal interconnection layer 302 onto the base substrate; and the power source connection line 40 is arranged at a same layer, and made of a same material, as the second signal interconnection layer 302.

Illustratively, the orthographic projection of the connection body 401 onto the base substrate at least partially overlaps with the orthographic projection of the first signal interconnection layer 301 onto the base substrate; and/or the orthographic projection of the connection body 401 onto the base substrate at least partially overlaps with the orthographic projection of the second signal interconnection layer 302 onto the base substrate. The orthographic projection of the connection protrusion 402 onto the base substrate at least partially overlaps with the orthographic projection of the first signal interconnection layer 301 onto the base substrate.

Based on the above, without the need for an additional patterning process, it is able to effectively reduce a layout space occupied by the power source connection line 40 and the signal interconnection layer at the lower frame region, ensure the insulation performance between the film layers for transmitting different signals, and ensure the reliability of the display substrate.

As shown in FIGS. 14 to 17, in some embodiments of the present disclosure, the first signal interconnection layer 301 surrounds the display region AA, at least one first aperture region K1 is formed at the lower frame region, and the connection protrusion 402 is arranged at a corresponding first aperture region K1; and/or the second signal interconnection layer 302 surrounds the display region AA, at least one second aperture region K2 is formed at the lower frame region, and the connection protrusion 402 is arranged at a corresponding second aperture region K2.

Illustratively, the at least one first aperture region K1 corresponds to the at least one connection protrusion 402 respectively, and the at least one second aperture region K2 corresponds to the at least one connection protrusion 402 respectively.

Based on the above, without the need for an additional patterning process, it is able to effectively reduce the layout space occupied by the power source connection line 40 and the signal interconnection layer at the lower frame region, ensure the insulation performance between the film layers for transmitting different signals, and ensure the reliability of the display substrate.

As shown in FIGS. 2 and 8, in some embodiments of the present disclosure, the display substrate includes at least two power source signal input ends VDD and at least two first signal ends VSS; the at least two power source signal input ends VDD include at least one power source terminal group Z2, and a power source terminal group Z2 in the at least one power source terminal group includes two power source signal input ends VDD of the at least two power source signal input ends arranged in a first direction; the at least two first signal ends VSS include at least one first terminal group Z1, and a first terminal group Z1 in the at least one first terminal group includes two first signal ends VSS of the at least two first signal ends arranged in the first direction; and an orthographic projection of the power source terminal group Z2 onto the base substrate is arranged between orthographic projections of the two first signal ends VSS in a corresponding first terminal group Z1 onto the base substrate.

As shown in FIG. 8, for example, the display substrate includes two power source signal input ends VDD and two first signal ends VSS. The two power source signal input ends VDD form a power source terminal group Z2, and the two first signal ends VSS form a first terminal group Z1. An orthographic projection of the power source terminal group Z2 onto the base substrate is arranged between orthographic projections of the two first signal ends VSS in the first terminal group Z1 onto the base substrate.

As shown in FIG. 2, for example, the display substrate includes four power source signal input ends VDD and four first signal ends VSS. The four power source signal input ends VDD form two power source terminal groups Z2 arranged in the first direction, and each power source terminal group Z2 includes two power source signal input ends VDD arranged in the first direction. The four first signal ends VSS form two first terminal groups Z1 arranged in the first direction, and each first terminal group Z1 includes two first signal ends VSS arranged in the first direction. The power source terminal groups Z2 correspond to the first terminal groups Z1 respectively. An orthographic projection of the power source terminal group Z2 onto the base substrate is arranged between orthographic projections of the two first signal ends VSS in the corresponding first terminal group Z1 onto the base substrate

As shown in FIGS. 2-4 and 8-10, in some embodiments of the present disclosure, the power source connection line 40 includes a connection body 401 and at least one connection protrusion 402, the connection body 401 is coupled to the at least one connection protrusion 402, the connection body 401 is arranged between the at least one connection protrusion 402 and the display region AA, the connection body 401 is coupled to the plurality of power source lines 41, the at least one connection protrusion 402 corresponds to the at least one power source terminal group Z2 respectively, and the connection protrusion 402 is coupled to the power source signal input ends VDD in a corresponding power source terminal group Z2.

As shown in FIG. 8, for example, the power source connection line 40 includes the connection body 401 and one connection protrusion 402, the connection body 401 is coupled to the connection protrusion 402, the display substrate includes one power source terminal group Z2, and the connection protrusion 402 is coupled to each power source signal input end VDD in the power source terminal group Z2.

As shown in FIG. 2, for example, the power source connection line 40 includes the connection body 401 and two connection protrusions 402, the connection body 401 is coupled to the two connection protrusions 402, the display substrate includes two power source terminal groups Z2, the connection protrusions 402 correspond to the power source terminal groups Z2 respectively, and the connection protrusion 402 is coupled to each power source signal input end VDD in a corresponding power source terminal group Z2.

As shown in FIGS. 2, 8 and 14, in some embodiments of the present disclosure, the peripheral region includes a first binding region and a second binding region; the first binding region is arranged between the second binding region and the display region AA; the display substrate further includes a flexible circuit board FPC and at least one driving chip IC, the at least one driving chip IC is bound to the first binding region, and the flexible circuit board FPC is bound to the second binding region; the flexible circuit board FPC is coupled to the power source signal input ends VDD and the first signal ends VSS; and the power source signal input ends VDD and the first signal ends VSS are arranged between the second binding region and the display region AA, and an orthographic projection of the first binding region onto the base substrate is arranged between orthographic projections of the two power source signal input ends VDD in a corresponding power source terminal group Z2 onto the base substrate.

As shown in FIG. 8, for example, the display substrate includes one driving chip IC and one power source terminal group Z2, the driving chip IC is arranged between the orthographic projections of the two power source signal input ends VDD in the power source terminal group Z2 onto the base substrate. For example, the display substrate includes one first binding region and one power source terminal group Z2, and the first binding region is arranged between the orthographic projections of the two power source signal input ends VDD in the power source terminal group Z2 onto the base substrate.

As shown in FIGS. 2 and 14, for example, the display substrate includes two driving chips IC and two power source terminal groups Z2, the driving chips IC correspond to the power source terminal groups Z2 respectively, and the driving chip IC is arranged between the orthographic projections of the two power source signal input ends VDD in the corresponding power source terminal group Z2 onto the base substrate. For example, the display substrate includes two first binding regions and two power source terminal groups Z2, the first binding regions correspond to the power source terminal groups Z2 respectively, and the first binding region is arranged between the orthographic projections of the two power source signal input ends VDD in the corresponding power source terminal group Z2 onto the base substrate.

The present disclosure further provides in some embodiments a display substrate, which includes a display region and a peripheral region located around the display region. The display substrate further includes a signal transmission layer, at least two signal interconnection layers laminated one on another, and a first signal end. The signal transmission layer extends from the display region to the peripheral region; and at least two signal interconnection layers and the first signal end are arranged at the peripheral region. Adjacent signal interconnection layers in the at least two signal interconnection layers are coupled to each other; the at least two signal interconnection layers include a first signal interconnection layer and a second signal interconnection layer, at least a portion of the second signal interconnection layer is arranged between the first signal interconnection layer and a base substrate of the display substrate, the first signal interconnection layer is coupled to the signal transmission layer, and the second signal interconnection layer is coupled to the first signal end. A first interconnection region is provided between the signal transmission layer and the first signal interconnection layer, the first interconnection region includes a plurality of sub-regions arranged sequentially in a direction from the display region to the peripheral region, and the signal transmission layer is coupled to the first signal interconnection layer at the plurality of sub-regions; the first signal interconnection layer includes a first portion, the second signal interconnection layer includes a second portion, a second interconnection region is formed between the second portion and the first portion, and the first portion is coupled to the second portion at the second interconnection region; an orthographic projection of a sub-region in the plurality of sub-regions proximate to the display region onto the base substrate at least partially overlaps with an orthographic projection of the first contact region onto the base substrate; and an orthographic projection of a sub-region in the plurality of sub-regions distal to the display region onto the base substrate at least partially overlaps with the orthographic projection of the first contact region onto the base substrate.

Illustratively, each sub-region corresponds to a second via-hole, and at the sub-region, the signal transmission layer is coupled to the first signal interconnection layer through the corresponding second via-hole.

Illustratively, the orthographic projection of each sub-region onto the base substrate at least partially overlaps with the orthographic projection of the first contact region onto the base substrate.

Illustratively, the orthographic projection of each sub-region onto the base substrate is located within the orthographic projection of the first contact region onto the base substrate.

In the display substrate provided in the embodiments of the present disclosure, the signal transmission layer is electrically coupled to the first signal end through the first signal interconnection layer and the second signal interconnection layer sequentially. In a case that a signal is transmitted between the signal transmission layer and the first signal end, the signal transmission is achieved through the second portion and the first portion simultaneously. The signal transmission layer is coupled to the first signal interconnection layer, so that the first signal interconnection layer is electrically coupled to the signal transmission layer at a plurality of frame regions. In this way, the signal is transmitted between the signal transmission layer and the signal interconnection layer in various direction, so as to improve the uniformity of the signal transmitted by the signal transmission layer in a display product in a better manner, thereby to provide a stable display effect and improve the display quality of the display substrate.

In the display substrate provided in the embodiments of the present disclosure, the signal is transmitted to the signal transmission layer through the second interconnection region, so in a case that the signal is transmitted through the first signal interconnection layer, the signal is transmitted simultaneously in a multi-layered manner. In this way, even in a case that the first signal interconnection layer has a small thickness, it is able to prevent the first signal interconnection layer from being damaged by the current during the transmission of the signal, thereby ensuring a good production yield of the display substrate.

The present disclosure further provides in some embodiments a display device, which includes the above-mentioned display substrate.

It should be appreciated that, the display device is any product or member having a display function, e.g., television, display, digital photo frame, mobile phone or tablet computer. The display device further includes a flexible circuit board, a printed circuit board, a back plate, etc.

In the display substrate provided in the embodiments of the present disclosure, the signal transmission layer 20 is electrically coupled to the first signal end VSS through the first signal interconnection layer 301 and the second signal interconnection layer 302 sequentially. In a case that a signal is transmitted between the signal transmission layer 20 and the first signal end VSS, the signal transmission is achieved through the second poritonL2 and the first portion L1 simultaneously. The signal transmission layer 20 is coupled to the first signal interconnection layer 301, so that the first signal interconnection layer 301 is electrically coupled to the signal transmission layer 20 at a plurality of frame regions. In this way, the signal is transmitted between the signal transmission layer and the signal interconnection layer in various direction, so as to improve the uniformity of the signal transmitted by the signal transmission layer in a display product in a better manner, thereby to provide a stable display effect and improve the display quality of the display substrate. In the display substrate provided in the embodiments of the present disclosure, the signal is transmitted to the signal transmission layer 20 simultaneously through the second portion L2 and the first portion L1, so the signal is transmitted through the first signal interconnection layer 301 simultaneously in a multi-layered manner. In this way, even in a case that the first signal interconnection layer 301 has a small thickness, it is able to prevent the loading of the first signal interconnection layer 301 from being too large, and ensure that the first signal interconnection layer 301 is not damaged by the current during the transmission of the signal, thereby ensuring a good production yield of the display substrate.

In a case that the display device includes the above-mentioned display substrate, it also has the above-mentioned beneficial effect, which will not be particularly defined herein.

It should be appreciated that, in the case that a signal line extends along a direction X, it means that a primary portion of the signal line, e.g., a line, a segment or a strip-like body, extends along the direction X, and an extension length of the primary portion is greater than an extension length of a secondary portion of the signal line, which is coupled to the primary portion, in the other direction.

It should be further appreciated that, the expression “at a same layer” refers to that the film layers are arranged on a same structural layer. Alternatively, for example, the film layers on a same layer may be layer structures formed through forming thin layers for forming specific patterns through a single-film-forming process and then patterning the film layers with a same mask through a single patterning process. Depending on different specific patterns, a single patterning process may include multiple exposing, development or etching processes, and the specific patterns in the layer structure may be continuous or discontinuous. These specific patterns may also be arranged at different levels or have different thicknesses.

In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above are merely the preferred embodiments of the present disclosure, but shall not be construed as limiting the scope of the present disclosure. Any person skilled in the art could readily conceive of changes or substitutions within the technical scope disclosed in the present disclosure, which shall fall within the protection scope of the present disclosure. Therefore, the protection scope of the present disclosure shall be subject to the protection scope of the claims.

1. A display substrate, comprising a display region and a peripheral region located around the display region, wherein the display substrate further comprises:
a signal transmission layer, wherein the signal transmission layer extends from the display region to the peripheral region; and
at least two signal interconnection layers laminated one on another, and a first signal end, wherein the at least two signal interconnection layers and the first signal end are arranged at the peripheral region,
wherein adjacent signal interconnection layers in the at least two signal interconnection layers are coupled to each other; the at least two signal interconnection layers comprise a first signal interconnection layer and a second signal interconnection layer, at least a portion of the second signal interconnection layer is arranged between the first signal interconnection layer and a base substrate of the display substrate, the second signal interconnection layer is coupled to the first signal end, and the first signal interconnection layer is coupled to the signal transmission layer;
a first contact region is provided between the signal transmission layer and the first signal interconnection layer; the first signal interconnection layer comprises a first portion, the second signal interconnection layer comprises a second portion, an interconnection region is formed between the second portion and the first portion, and the first portion is coupled to the second portion at the interconnection region; and an orthographic projection of the interconnection region onto the base substrate at least partially overlaps with an orthographic projection of the first contact region onto the base substrate.

2. The display substrate according to claim 1, wherein the first portion is arranged on a surface of the second portion distal to the base substrate; or the first portion is coupled in parallel with the second portion.

3. The display substrate according to claim 2, wherein the first portion is directly lapped onto the second portion.

4. The display substrate according to claim 2, comprising an insulation layer, wherein the insulation layer is arranged between the first signal interconnection layer and the second signal interconnection layer;
the insulation layer is provided with a first via-hole, the first portion is located in the first via-hole, and the first portion is in contact with the surface of the second portion distal to the base substrate; or the insulation layer is provided with at least two second via-holes, and the first portion is coupled in parallel with the second portion through the at least two second via-holes.

5. The display substrate according to claim 2, wherein the signal transmission layer comprises a cathode layer; and the display substrate further comprises an anode layer, and the first signal interconnection layer is arranged at a same layer, and made of a same material, as the anode layer.

6. The display substrate according to claim 5, wherein the peripheral region comprises a lower frame region; the display substrate further comprises:
a power source connection line and at least two power source signal input ends, wherein the at least two power source signal input ends and the power source connection line are arranged in the lower frame region;
a plurality of power source lines, wherein the plurality of power source lines is arranged in the display region;
wherein the power source connection line is coupled to each of the plurality of power source lines, and at least a portion of an orthographic projection of the power source connection line onto the base substrate is arranged between an orthographic projection of the first signal interconnection layer onto the base substrate and the display region; and the power source connection line is further coupled to each of the at least two power source signal input ends, and the at least two power source signal input ends are arranged at a side of the power source connection line distal to the display region.

7. The display substrate according to claim 6, wherein the first signal interconnection layer surrounds the display region.

8. The display substrate according to claim 6, wherein the at least two signal interconnection layers further comprise a third signal interconnection layer, at least a portion of the third signal interconnection layer is arranged between the second signal interconnection layer and the base substrate, and the second signal interconnection layer is coupled to the first signal end through the third signal interconnection layer.

9. The display substrate according to claim 8, comprising a first metal layer and a second metal layer arranged sequentially in that order in a direction away from the base substrate, wherein the second signal interconnection layer is arranged at the second metal layer, and the third signal interconnection layer is arranged at the first metal layer.

10. The display substrate according to claim 6, wherein the at least two signal interconnection layers further comprise a third signal interconnection layer and a fourth signal interconnection layer; the fourth signal interconnection layer, the third signal interconnection layer and the second signal interconnection layer are arranged sequentially in that order in a direction away from the base substrate; and the second signal interconnection layer is coupled to the first signal end through the third signal interconnection layer and the fourth signal interconnection layer.

11. The display substrate according to claim 10, further comprising a first metal layer, a second metal layer and a third metal layer arranged sequentially in that order in the direction away from the base substrate, wherein the second signal interconnection layer is arranged at the third metal layer, the third signal interconnection layer is arranged at the second metal layer, and the fourth signal interconnection layer is arranged at the first metal layer.

12. The display substrate according to claim 8, wherein the second signal interconnection layer surrounds the display region;
the power source connection line comprises a connection body and a connection protrusion coupled to each other, the connection body is arranged between the connection protrusion and the display region, the connection body is coupled to each of the plurality of power source lines, and the connection protrusion is coupled to the power source signal input end;
at least a portion of an orthographic projection of the connection body onto the base substrate is arranged between the orthographic projection of the first signal interconnection layer onto the base substrate and the display region; an orthographic projection of the connection protrusion onto the base substrate at least partially overlaps with the orthographic projection of the first signal interconnection layer onto the base substrate; and/or the orthographic projection of the connection protrusion onto the base substrate at least partially overlaps with an orthographic projection of the second signal interconnection layer onto the base substrate.

13. (canceled)

14. The display substrate according to claim 6, further comprising a first metal layer, wherein the second signal interconnection layer is arranged at the first metal layer.

15. The display substrate according to claim 6, wherein the power source connection line comprises a connection body and a connection protrusion coupled to each other, the connection body is arranged between the connection protrusion and the display region, the connection body is coupled to each of the plurality of power source lines, and the connection protrusion is coupled to the power source signal input end;
at least a portion of an orthographic projection of the connection body onto the base substrate is arranged between the orthographic projection of the first signal interconnection layer onto the base substrate and the display region; an orthographic projection of the connection protrusion onto the base substrate does not overlap with the orthographic projection of the first signal interconnection layer onto the base substrate; and/or the orthographic projection of the connection protrusion onto the base substrate does not overlap with an orthographic projection of the second signal interconnection layer onto the base substrate; and the power source connection line is arranged at a same layer, and made of a same material, as the second signal interconnection layer.

16. The display substrate according to claim 15, wherein the first signal interconnection layer surrounds the display region, at least one first aperture region is formed at the lower frame region, and the connection protrusion is arranged at a corresponding one of the at least one first aperture region; and/or the second signal interconnection layer surrounds the display region, at least one second aperture region is formed at the lower frame region, and the connection protrusion is arranged at a corresponding one of the at least one second aperture region.

17. The display substrate according to claim 6, wherein the display substrate comprises at least two power source signal input ends and at least two first signal ends; the at least two power source signal input ends are divided into at least one power source terminal group, and the power source terminal group comprises two power source signal input ends of the at least two power source signal input ends arranged in a first direction; the at least two first signal ends are divided into at least one first terminal group, and the first terminal group comprises two first signal ends of the at least two first signal ends arranged in the first direction; and an orthographic projection of the power source terminal group onto the base substrate is arranged between orthographic projections of the two first signal ends in a corresponding first terminal group onto the base substrate.

18. The display substrate according to claim 17, wherein the power source connection line comprises a connection body and at least one connection protrusion, the connection body is coupled to each of the at least one connection protrusion, the connection body is arranged between the connection protrusion and the display region, the connection body is coupled to each of the plurality of power source lines, the at least one connection protrusion corresponds to the at least one power source terminal group respectively, and the connection protrusion is coupled to each of the power source signal input ends in a corresponding power source terminal group.

19. The display substrate according to claim 17, wherein the peripheral region comprises a first binding region and a second binding region; the first binding region is arranged between the second binding region and the display region; the display substrate further comprises a flexible circuit board and at least one driving chip, the at least one driving chip is bound to the first binding region, and the flexible circuit board is bound to the second binding region;
the flexible circuit board is coupled to each of the power source signal input ends and each of the first signal ends; and each of the power source signal input ends and each of the first signal ends are arranged between the second binding region and the display region, and an orthographic projection of the first binding region onto the base substrate is arranged between orthographic projections of the two power source signal input ends in a corresponding power source terminal group onto the base substrate.

20. A display substrate, comprising a display region and a peripheral region located around the display region, wherein the display substrate further comprises:
a signal transmission layer, wherein the signal transmission layer extends from the display region to the peripheral region;
at least two signal interconnection layers laminated one on another, and a first signal end, wherein the at least two signal interconnection layers and the first signal end are arranged at the peripheral region,
wherein adjacent signal interconnection layers in the at least two signal interconnection layers are coupled to each other; the at least two signal interconnection layers comprise a first signal interconnection layer and a second signal interconnection layer, at least a portion of the second signal interconnection layer is arranged between the first signal interconnection layer and a base substrate of the display substrate, the second signal interconnection layer is coupled to the first signal end, and the first signal interconnection layer is coupled to the signal transmission layer;
a first interconnection region is provided between the signal transmission layer and the first signal interconnection layer, the first interconnection region comprises a plurality of sub-regions arranged sequentially in a direction from the display region to the peripheral region, and the signal transmission layer is coupled to the first signal interconnection layer at the plurality of sub-regions;
the first signal interconnection layer comprises a first portion, the second signal interconnection layer comprises a second portion, a second interconnection region is formed between the second portion and the first portion, and the first portion is coupled to the second portion at the second interconnection region; an orthographic projection of a sub-region in the plurality of sub-regions proximate to the display region onto the base substrate at least partially overlaps with an orthographic projection of the first contact region onto the base substrate; and
an orthographic projection of a sub-region in the plurality of sub-regions distal to the display region onto the base substrate at least partially overlaps with the orthographic projection of the first contact region onto the base substrate.

21. A display device, comprising the display substrate according to claim 1.
